(19) United States
(12) Patent Application Publication
(10) Pub. No.: US 2025/0239518 A1
(43) Pub. Date: Jul. 24, 2025

(54) PACKAGE SUBSTRATE WITH EMBEDDED CAPACITOR PACKAGE HAVING REDISTRIBUTION LAYER(S) (RDL(s)) FOR ALIGNING CAPACITOR TERMINALS CONNECTIONS TO SEMICONDUCTOR DIE IN AN INTEGRATED CIRCUIT (IC) PACKAGE, AND RELATED FABRICATION METHODS

(71) Applicant: QUALCOMM Incorporated, San Diego, CA (US)

(72) Inventors: Aniket Patil, San Diego, CA (US); Joan Rey Villarba Buot, Escondido, CA (US); Piyush Gupta, San Diego, CA (US)

(21) Appl. No.: 18/418,505

(22) Filed: Jan. 22, 2024

(51) Int. Cl. H01L 23/522; H01L 23/00; H01L 23/498

(52) U.S. Cl. CPC H01L 23/5223; H01L 23/49822; H01L 23/49838; H01L 24/16; H01L 2224/16225; H01L 2924/19041

(57) ABSTRACT

Package substrate with embedded capacitor package with a redistribution layer(s) (RDL(s)) for aligning capacitor terminals to die interconnects of a semiconductor die (“die”) in an integrated circuit (IC) package, and related IC packages and fabrication methods. The capacitor package can be embedded in a package substrate of an IC package, such as to provide a decoupling capacitance or filter for a die of the IC package. A RDL(s) is built on a substrate of a capacitor of the capacitor package such that RDL interconnects of the RDL(s) are coupled to capacitor terminals of the capacitor. The RDL(s) redistributes connections to the capacitor terminals of the capacitor, to a desired pattern and/or pitch to align the capacitor terminals with die interconnects of a die coupled to the package substrate of the IC package. This minimizes signal path length between the capacitor and die to minimize inductance in the capacitive loop.

### BACKGROUND

### I. Field of the Disclosure

The field of the disclosure relates to integrated circuit (IC) packages that include a substrate with an embedded capacitor(s) (e.g., a silicon capacitor(s)), and more particularly bump out of the embedded capacitor coupled to metal interconnects in the substrate to provide signal routing paths to a semiconductor die (“die”) coupled to the substrate.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a substrate as a routing substrate (e.g., a package substrate) to provide physical support and an electrical interface to the die(s). The die(s) is electrically interfaced to metal interconnects (e.g., metal traces) exposed in an upper layer of the substrate as part of signal routing paths. The substrate also includes one or more metallization layers that include metal interconnects (e.g., metal traces, metal lines) with vertical interconnect accesses (vias) coupling the metal interconnects together between adjacent metallization layers to provide electrical interfaces between the dies. If the substrate is a package substrate, the substrate also includes a lower, outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

A passive electrical device, such as a capacitor, may be embedded in an embedded package substrate (EPS) of an IC package and electrically coupled to a die coupled to the package substrate to provide a desired circuit function for the coupled die. For example, an electrical device may be embedded in a core layer of a cored package substrate. Embedding an electrical device in the package substrate may serve to locate the electrical device closer to a coupled die to minimize the signal path length between the electrical device and the die. The embedded capacitor is electrically coupled to die interconnects of a die in the IC package by being coupled to interconnected metal traces in one or more metallization layers of a package substrate, which are coupled to conductive bumps (e.g., solder bumps) coupled to die interconnects of the die. For example, a passive electrical device such as a capacitor in the form of a silicon capacitor (e.g., deep trench capacitor (DTC)) may be embedded in the package substrate and coupled to a die to provide a decoupling capacitance as part of a power distribution network (PDN) in the IC package. A capacitor can also be used to provide a bypass capacitance to provide a low impedance shunt path to high-frequency noise signals. In either case, it is desired to minimize the signal path length between the capacitor and the die to minimize inductance in the connection path so as to not reduce the ability of the capacitor to store energy that will be discharged during transient power supply events for decoupling capacitance or in response to high-frequency signals.

### SUMMARY OF THE DISCLOSURE

Aspects disclosed herein include a package substrate with an embedded capacitor package having a redistribution layer(s) (RDL(s)) for aligning capacitor terminal connections of a capacitor to a semiconductor die (“die”) in an integrated circuit (IC) package. Related integrated circuit (IC) packages and fabrication methods are also disclosed. The capacitor package can be embedded in a package substrate of an IC package to provide a decoupling capacitance or filter to the die, wherein the package substrate provides signal routing paths between the capacitor in the capacitor package and the die as a routing substrate. In this regard, in exemplary aspects, the embedded capacitor package includes a RDL(s) formed on a substrate of the capacitor such that RDL interconnects (e.g., metal traces) of the RDL(s) are coupled to capacitor terminals of the capacitor. A RDL is a metal layer that can be added and patterned during fabrication of a substrate to allow for the formation of finer pitch metal interconnects that can be matched to the pitch of a coupled component. In this regard, the RDL(s) redistributes the connections to the capacitor terminals of the capacitor to a desired pattern and/or pitch. In this manner, the capacitor package can be embedded in the package substrate of an IC package such that the RDL interconnects of the RDL(s) align connections to the capacitor terminals of the capacitor with die interconnects of a die coupled to the package substrate of the IC package to minimize the signal path length between the capacitor and the die. Minimizing the connection path between the capacitor and the die minimizes the inductance in the capacitive loop of the capacitor. Minimizing the inductance in the capacitive loop can be important so as not to reduce the effective capacitance of the capacitor for its intended application (e.g., a decoupling capacitance, bypass capacitance). Also, minimizing the reduction in capacitance in the capacitive loop of the capacitor may avoid the need to provide additional capacitors in the IC package to obtain the needed or desired capacitance.

As an example, the capacitor package embedded in a package substrate can include a silicon capacitor package that includes a silicon capacitor formed in a silicon substrate with one or more RDLs formed on the substrate. For example, the silicon capacitor may be a deep trench capacitor (DTC) that includes vertical capacitors formed by etched deep trenches in a silicon substrate. The trenches of the silicon capacitor include adjacent electrodes that are separated by a dielectric layer to form capacitors. The capacitor includes metal layers each connected to an electrode of the capacitor and having exposed metal pads that can be bumped with external bumps (e.g., with solder bumps) to provide external terminals for the capacitor. A RDL can be formed on the silicon substrate of the capacitor with RDL interconnects of the RDL(s) coupled to the external bumps of the capacitor package. Additional RDLs can be formed on the substrate of the capacitor as part of the silicon capacitor package to redistribute the connections to the capacitor external bumps to the desired pattern and/or pitch. In this manner, the silicon capacitor package can be embedded in a package substrate of an IC package such that the RDL interconnects of the built-on RDL(s) align connections of the external bumps of the capacitor package with die interconnects of a die coupled to the package substrate of the IC package to minimize the signal path length between the capacitor and the die.

In this regard, in one exemplary aspect, a package substrate is provided. The package substrate comprises a first metallization layer comprising a plurality of first metal interconnects having a first pitch in a first direction. The package substrate also comprises a capacitor package comprising a capacitor. The capacitor comprises a capacitor substrate comprising a first surface, and a plurality of capacitor terminals having a second pitch in the first direction different than the first pitch. The capacitor package also comprises a RDL substrate adjacent to the capacitor substrate. The RDL substrate comprises a first RDL comprising a plurality of first RDL interconnects each coupled to a capacitor terminal of the plurality of capacitor terminals and each coupled to a first metal interconnect of the plurality of first metal interconnects.

In another exemplary aspect, a method of fabricating a package substrate is provided. The method comprises providing a first metallization layer comprising a plurality of first metal interconnects having a first pitch in a first direction. The method also comprises providing a capacitor package comprising providing a capacitor, comprising forming a capacitor substrate comprising a first surface, and forming a plurality of capacitor terminals having a second pitch in the first direction different than the first pitch. Providing the capacitor package also comprises forming a RDL substrate adjacent to the capacitor substrate, comprising forming a first RDL comprising a plurality of first RDL interconnects adjacent to the capacitor substrate, and coupling each first RDL interconnect of the plurality of first RDL interconnects to a capacitor terminal of the plurality of capacitor terminals and to a first metal interconnect of the plurality of first metal interconnects.

In another exemplary aspect, an IC package is provided. The IC package comprises a package substrate, comprising a first metallization layer comprising a plurality of first metal interconnects having a first pitch in a first direction, and a capacitor package. The capacitor package comprises a capacitor, comprising a capacitor substrate comprising a first surface, and a plurality of capacitor terminals having a second pitch in the first direction different than the first pitch. The capacitor package also comprises a RDL substrate adjacent to the capacitor substrate. The RDL substrate comprises a first RDL comprising a plurality of first RDL interconnects each coupled to a capacitor terminal of the plurality of capacitor terminals and each coupled to a first metal interconnect of the plurality of first metal interconnects. The IC package also comprises a die comprising a plurality of die interconnects having the first pitch in the first direction and each coupled to a first metal interconnect of the plurality of first metal interconnects.

### BRIEF DESCRIPTION OF THE FIGURES

FIG. 1A is a side view of an exemplary integrated circuit (IC) package that includes a package substrate with a capacitor in the form of a silicon capacitor embedded in a core layer, wherein the silicon capacitor is coupled to a die coupled to the package substrate through entangled connections in the package substrate;

FIGS. 1B-1D are top views of respective patterns of the capacitor terminals of the silicon capacitor, the metal interconnects of the package substrate coupled to the capacitor terminals, and the die interconnects of the die in the IC package in FIG. 1A;

FIGS. 2A and 2B are a side view and a close-up side view, respectively, of an exemplary IC package that includes a cored package substrate with a capacitor package embedded in a core layer, wherein the capacitor package includes a RDL(s) formed on a substrate of a capacitor that has RDL interconnects coupled to capacitor terminals of the capacitor to redistribute the connections to the capacitor terminals to be aligned with die interconnects of a die coupled to the package substrate of the IC package to minimize the signal path length between the capacitor and the die;

FIGS. 2C-2E are top views of respective exemplary interconnect patterns that can be provided for the capacitor terminals of the capacitor, RDL interconnects of a RDL of the capacitor package, and die interconnects of the die in the IC package in FIGS. 2A and 2B;

FIGS. 2F-2H are top views of respective other exemplary interconnect patterns that can be provided for the capacitor terminals of the capacitor, the RDL interconnects of a RDL of the capacitor package, and the die interconnects of the die in the IC package in FIGS. 2A and 2B;

FIG. 3 is a side view of another exemplary IC package that includes a cored package substrate with a capacitor package embedded in a metallization layer(s) of the cored package substrate, wherein the capacitor package includes a RDL(s) formed on a substrate of a capacitor that has RDL interconnects coupled to capacitor terminals of the capacitor to redistribute the connections to the capacitor terminals to be aligned with die interconnects of a die coupled to the package substrate of the IC package to minimize the signal path length between the capacitor and the die;

FIG. 4 is a side view of another exemplary IC package that includes a coreless package substrate with an embedded capacitor package, wherein the capacitor package includes a RDL(s) formed on a substrate of a capacitor that has RDL interconnects coupled to capacitor terminals of the capacitor to redistribute the connections to the capacitor terminals to be aligned with die interconnects of a die coupled to the package substrate of the IC package to minimize the signal path length between the capacitor and the die;

FIG. 5 is a flowchart illustrating an exemplary process of fabricating a package substrate that includes an embedded capacitor package that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in an IC package, to minimize the signal path length between the capacitor and the die, including, but not limited to, the capacitors and IC packages in FIGS. 2A-4;

FIGS. 6A and 6B is a flowchart illustrating a fabrication process of fabricating capacitor packages that each include a RDL(s) formed on a substrate of a capacitor with RDL interconnects of the RDL(s) coupled to capacitor terminals of the capacitor to redistribute the connections to the capacitor terminals, such that the capacitor package can be provided in an IC package with the connections of the capacitor terminals of the capacitor aligned with die interconnects of a die coupled to the package substrate of the IC package to minimize the signal path length between the capacitor and the die, including, but not limited to, the capacitors in FIGS. 2A-4;

FIGS. 7A-7H are exemplary fabrication stages during fabrication of the capacitors according to the exemplary fabrication process in FIGS. 6A and 6B;

FIGS. 8A-8E is a flowchart illustrating a fabrication process of fabricating a package substrate that includes an embedded capacitor package that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in an IC package to minimize the signal path length between the capacitor and the die, including, but not limited to, the capacitors and IC packages in FIGS. 2A-4;

FIGS. 9A-9I are exemplary fabrication stages during fabrication of the package substrate according to the exemplary fabrication process in FIGS. 8A-8E;

FIG. 10 is a block diagram of an exemplary wireless communications device that includes one or more IC packages that include a package substrate with an embedded capacitor package(s), including, but not limited to, the capacitor packages in FIGS. 2A-4, 7H, and 9I, that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the signal path length between the capacitor and the die, including, but not limited to, the IC packages in FIGS. 2A-4 and 9I, and that can be fabricated according to a fabrication process, including, but not limited to, the exemplary fabrication processes in FIGS. 5, 6A-6B, and 8A-8E; and

FIG. 11 is a block diagram of an exemplary electronic device in the form of a processor-based system that includes one or more IC packages that include a package substrate with an embedded capacitor package(s), including, but not limited to, the capacitor packages in FIGS. 2A-4, 7H, and 9I, that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the signal path length between the capacitor and the die, including, but not limited to, the IC packages in FIGS. 2A-4 and 9I, and that can be fabricated according to a fabrication process, including, but not limited to, the exemplary fabrication processes in FIGS. 5, 6A-6B, and 8A-8E.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include package substrates with embedded capacitor package having a redistribution layer(s) (RDL(s)) for aligning capacitor terminal connections of a capacitor to a semiconductor die (“die”) in an integrated circuit (IC) package. Related integrated circuit (IC) packages and fabrication methods are also disclosed. The capacitor package can be embedded in a package substrate of an IC package to provide a decoupling capacitance or filter to the die, wherein the package substrate provides signal routing paths between the capacitor in the capacitor package and the die as a routing substrate. In this regard, in exemplary aspects, that embedded capacitor package includes a RDL(s) formed on a substrate of the capacitor such that RDL interconnects (e.g., metal traces) of the RDL(s) are coupled to capacitor terminals of the capacitor. A RDL is a metal layer that can be added and patterned during fabrication of a substrate to allow for the formation of finer pitch metal interconnects that can be matched to the pitch of a coupled component. In this regard, the RDL(s) redistribute the connections to the capacitor terminals of the capacitor to a desired pattern and/or pitch. In this manner, the capacitor package can be embedded in the package substrate of an IC package such that the RDL interconnects of the RDL(s) align the connections to the capacitor terminals of the capacitor with die interconnects of a die coupled to the package substrate of the IC package to minimize the signal path length between the capacitor and the die. Minimizing the connection path between the capacitor and the die minimizes the inductance in the capacitive loop of the capacitor. Minimizing the inductance in the capacitive loop can be important so to not reduce the effective capacitance of the capacitor for its intended application (e.g., a decoupling capacitance, bypass capacitance). Also, minimizing reduction in capacitance in the capacitive loop of the capacitor may avoid the need to provide additional capacitors in the IC package to obtain the needed or desired capacitance.

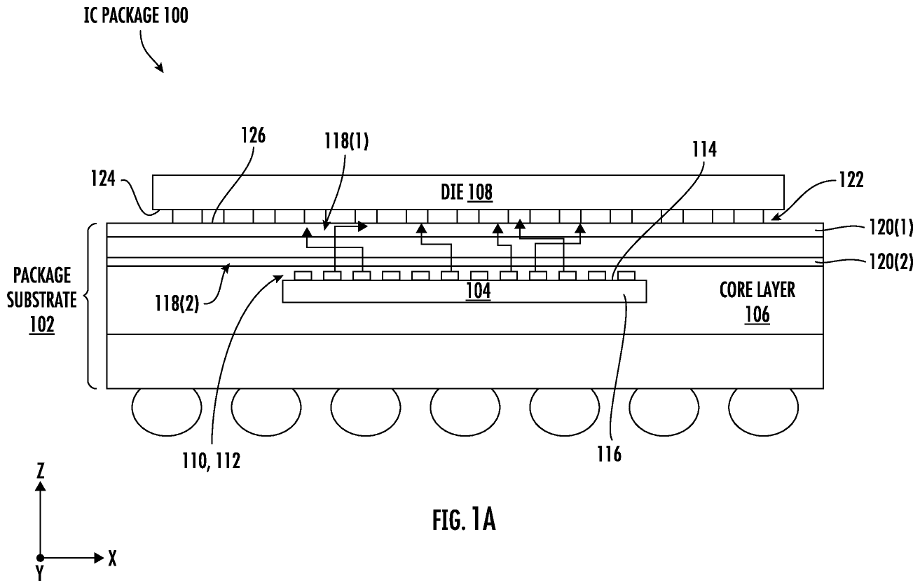

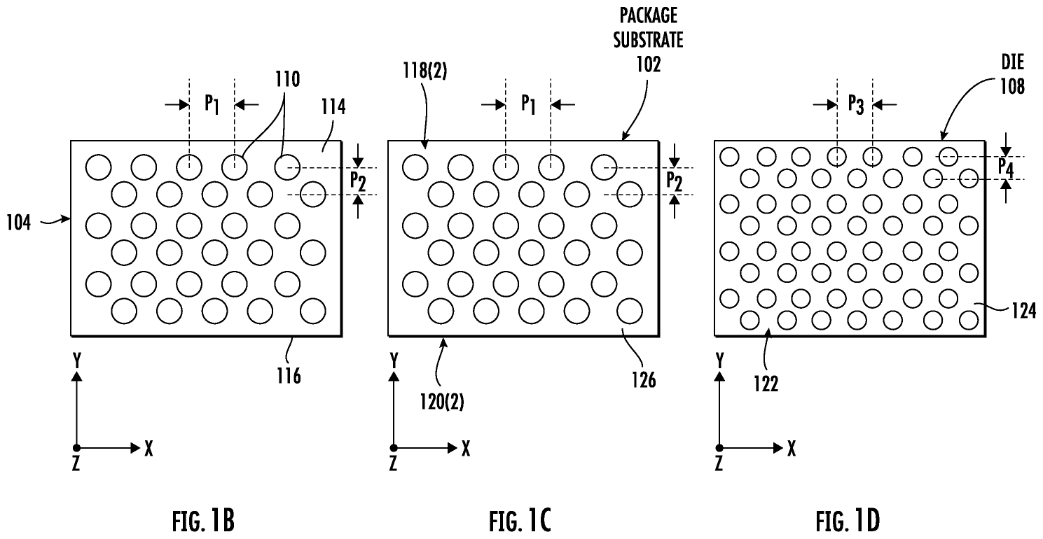

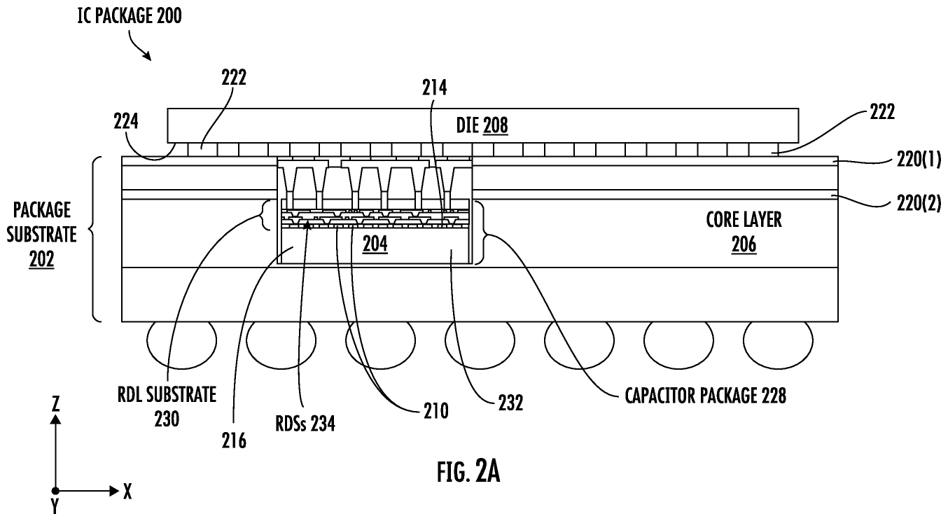

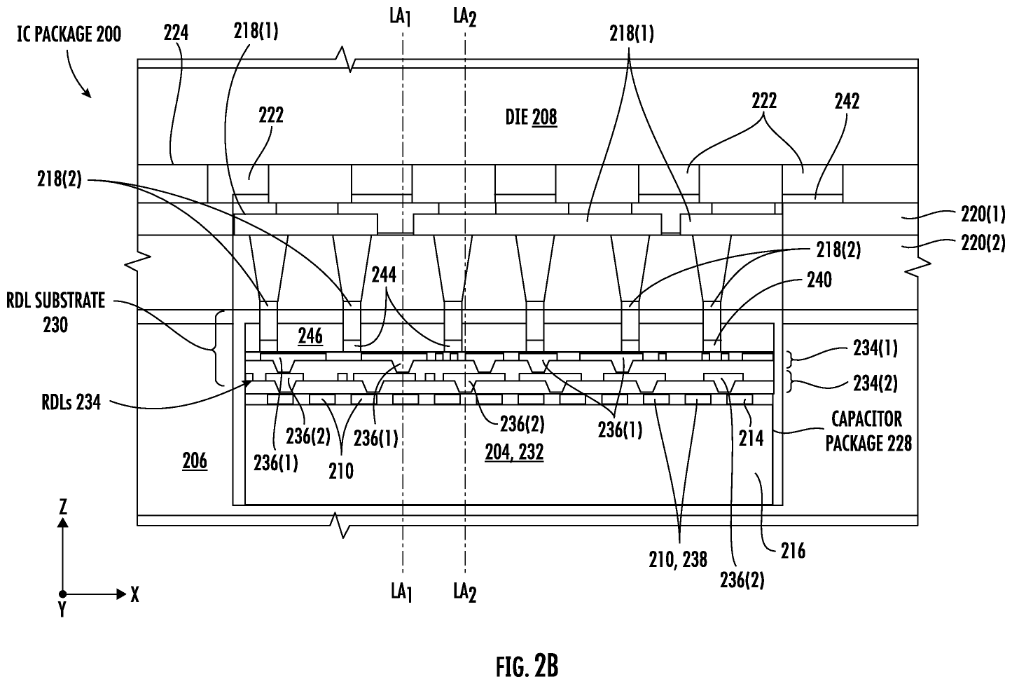

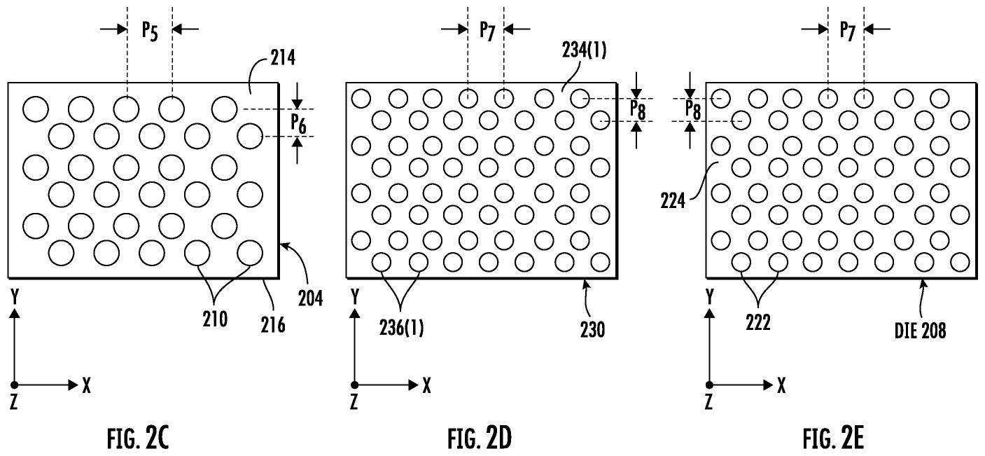

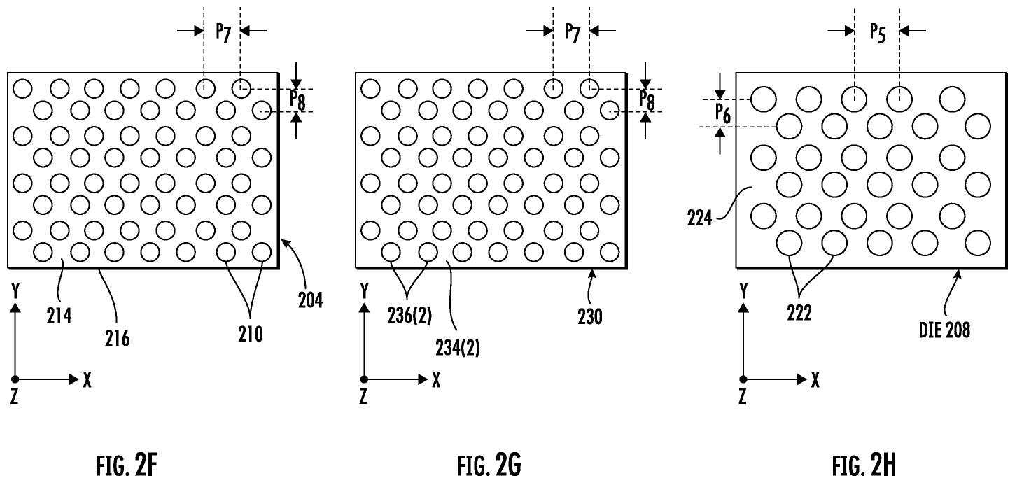

Before discussing examples of package substrates that can be provided in an IC package, wherein the package substrates include an embedded capacitor package(s), that includes a RDL(s) formed on a substrate of a capacitor to align connections to capacitor terminals of the capacitor with die interconnects of a die coupled to the package substrate in the IC package starting at FIG. 2A, an exemplary IC package 100 that does not include such a capacitor package is first described with regard to FIGS. 1A-1D.

In this regard, FIG. 1A is a side view of an exemplary IC package 100 that includes a package substrate 102 with an embedded silicon capacitor 104. For example, the silicon capacitor 104 can be a deep trench capacitor (DTC). In this example, the silicon capacitor 104 is embedded in a core layer 106 of the package substrate 102 as a cored package substrate. The silicon capacitor 104 may be included in the IC package 100 to provide a decoupling capacitance or filter capacitance for a circuit in a die 108 in the package substrate 102. In this regard, the silicon capacitor 104 includes capacitor terminals 110 in the form of interconnect bumps 112 that are exposed from a first surface 114 of a capacitor substrate 116 in which capacitors of the silicon capacitor 104 are formed. To electrically couple the silicon capacitor 104 to the die 108, the capacitor terminals 110 are coupled to first metal interconnects 118(1) in a first metallization layer 120(1) of the package substrate 102. The capacitor terminals 110 are coupled to second metal interconnects 118(2) in a second metallization layer 120(2) in the package substrate 102, wherein the second metallization layer 120(2) is disposed on and/or adjacent to the first surface 114 of the capacitor substrate 116. Connections are made and routed from the second metal interconnects 118(2) in the second metallization layer 120(2) to the first metal interconnects 118(1) in the first metallization layer 120(1) of the package substrate 102 Die interconnects 122 of the die 108, which are exposed from a bottom surface 124 of the die 108, are coupled to the first metal interconnects 118(1) exposed from a first, outer surface 126 of the first metallization layer 120(1) to provide an electrical coupling between the die 108 and the silicon capacitor 104.

However, as shown in FIG. 1A, these routed connections in the package substrate 102 between the second and first metal interconnects 118(2), 118(1) from the capacitor terminals 110 of the silicon capacitor 104 to the die interconnects 122 are “entangled” signal routing paths. This means that these connections must be routed not only vertically in a second, vertical direction (Z-axis direction), but also horizontally in a first, horizontal direction(s) (X-axis and/or Y-axis directions) to route the connections to couple the capacitor terminals 110 of the silicon capacitor 104 to the die interconnects 122 of the die 108. This is also shown in FIGS. 1B-1D, which illustrate top views of the capacitor terminals 110 exposed from the first surface 114 of the capacitor substrate 116 (FIG. 1B), the second metal interconnects 118(2) in the second metallization layer 120(2) coupled to the capacitor terminals 110 (FIG. 1C), and the die interconnects 122 of the die 108 (FIG. 1D). As shown in FIGS. 1B and 1C, the alignment of connections of the capacitor terminals 110 and the second metal interconnects 118(2) are aligned in both first, horizontal directions (X-axis and Y-axis directions), and have the same pitches P₁, P₂ in the respective first, horizontal directions (X-axis and Y-axis directions). However, as shown in FIG. 1D, the die interconnects 122 of the die 108 are not aligned with the capacitor terminals 110 of the silicon capacitor 104 in both first, horizontal directions (X-axis and Y-axis directions). For example, certain die interconnects 122 have smaller pitches P₃, P₄ in both first, horizontal directions (X-axis and Y-axis directions) than the pitches P₁, P₂ of the closest aligned capacitor terminals 110 in the second, vertical direction (Z-axis direction).

Entangled signal routing paths between the silicon capacitor 104 and the die 108 increases the signal path lengths between the silicon capacitor 104 and the die 108. This increases inductance in the signal routing paths between the silicon capacitor 104 and the die 108. It is generally desired to minimize the signal path length between the silicon capacitor 104 and the die 108 to minimize inductance in the connection path so as to not reduce the ability of the silicon capacitor 104 to store energy that will be discharged during transient power supply events for decoupling capacitance or in response to high-frequency signals.

To reduce the amount of entangled signal routing paths between a capacitor and die in the IC package, an IC package 200 in FIGS. 2A and 2B is provided. As discussed in more detail below, FIG. 2A is a side view of the IC package 200 that includes a capacitor package 228 that includes a RDL substrate 230 formed on or adjacent to a first surface 214 of a capacitor substrate 216 of a capacitor 232 in the form of a silicon capacitor 204 in this example. For example, the capacitor substrate 216 can be a silicon substrate in which capacitive elements are formed. As an example, the silicon capacitor 204 can be a deep trench capacitor (DTC). The RDL substrate 230 is a substrate that includes one or more RDLs. As shown in FIG. 2A and in more detail in FIG. 2B, the RDL substrate 230 includes one or more RDLs 234, which is two (2) RDLs 234(1), 234(2) in this example, to redistribute the connections from capacitor terminals 210 of the silicon capacitor 204 to die interconnects 222 of a die 208 exposed from a bottom surface 224 of the die 208. The RDLs 234(1), 234(2) redistribute the connections from the capacitor terminals 210 of the silicon capacitor 204 to the die interconnects 222 of the die 208 so as to align connections to the capacitor terminals 210 and the die interconnects 222 to minimize the signal path length between the die 208 and the silicon capacitor 204 to minimize resistance and/or inductance in the capacitive loop provided by the silicon capacitor 204. For example, if the silicon capacitor 204 is coupled to power and ground connections of the die 208, the silicon capacitor 204 provides a decoupling capacitance for a power distribution network (PDN) of the IC package 200 and the die 208. If the silicon capacitor 204 is coupled to a filtering circuit in the die 208, the silicon capacitor 204 provides a capacitor for such filtering circuit. In either case, minimizing the signal path length between the die 208 and the silicon capacitor 204 is desired.

As further shown in FIG. 2B, in this example, the capacitor package 228 is fully embedded in a package substrate 202. Such is not required. For example, the capacitor package 228 could be only partially embedded in the package substrate 202 in the first, horizontal direction (X-axis and Y-axis directions) and/or the second, vertical direction (Z-axis direction). As an example, the package substrate 202 could be a modified semi-additive process (mSAP) substrate that is formed by forming metallization layers in an additive process. The package substrate 202 could also be an embedded trace substrate (ETS). As another example, the package substrate 202 could be an interposer substrate that provides signal routing paths between multiple package layers, such as in a three-dimensional IC (3DIC) package.

In this example, the capacitor package 228 is embedded in a core layer 206 of the package substrate 202. The core layer 206 is adjacent to a second metallization layer 220(2) in the second, vertical direction (Z-axis direction), which is adjacent to the RDL substrate 230 the second, vertical direction (Z-axis direction). The second metallization layer 220(2) includes second metal interconnects 218(2) that are coupled to first RDL interconnects 236(1) (e.g., metal traces) in a first RDL 234(1) as part of the RDL substrate 230. A RDL 234, including the first RDL 234(1) is a metal layer that can be added and patterned during fabrication of a substrate, such as the capacitor substrate 216, to allow for the formation of finer pitch metal interconnects/traces that can be matched to the pitch of a coupled component. The second metal interconnects 218(2) in the second metallization layer 220(2) are coupled to first metal interconnects 218(1) in a first metallization layer 220(1), which are exposed from a first, outer surface 226 of the package substrate 202. The die interconnects 222 are coupled to the first metal interconnects 218(1). In this manner, the die interconnects 222 are coupled to the first RDL interconnects 236(1) (e.g., metal traces) of the first RDL 234(1) of the RDL substrate 230, through the connections between the first and second metal interconnects 218(1), 218(2). As discussed in more detail below, the first RDL interconnects 236(1) of the first RDL 234(1) can be formed and patterned to align with the die interconnects 222 of the die 208 so as to provide an aligned connection between the die 208 and the RDL substrate 230.

With continuing reference to FIG. 2B, the RDL substrate 230 in this example also includes the second RDL 234(2) that includes second RDL interconnects 236(2). Like the first RDL 234(1), the second RDL 234(2) is a metal layer that can be added and patterned during fabrication of a substrate, such as the capacitor substrate 216, to allow for the formation of finer pitch metal interconnects/traces that can be matched to the pitch of a coupled component. The second RDL interconnects 236(2) are coupled to respective capacitor terminals 210 of the silicon capacitor 204 exposed from the first surface 214 of the capacitor substrate 216. In this example, the capacitor terminals 210 are first interconnect bumps 238 that are formed on the first surface 214 of the capacitor substrate 216 and coupled to electrodes internal to the silicon capacitor 204. For example, the first interconnect bumps 238 may be solder bumps that form a solder joint between the capacitor terminals 210 and the second RDL interconnects 236(2). The first interconnect bumps 238 could also be ball grid array (BGA) interconnects as another example. The coupling of the capacitor terminals 210 to the second RDL interconnects 236(2) of the second RDL 234(2) provides an electrical coupling between the capacitor terminals 210 and the die interconnects 222, through the coupling of the second RDL interconnects 236(2) to the first RDL interconnects 236(1), which are coupled to the die interconnects 222. In this manner, the silicon capacitor 204 is coupled to the die 208 to provide a capacitance in a circuit to the die 208, such as a decoupling capacitance or capacitance for a filter circuit.

In this example, the RDL substrate 230 includes second interconnect bumps 240 that are formed on the first RDL interconnects 236(1) and are coupled to the second metal interconnects 218(2) to couple the first RDL interconnects 236(1) to the second metal interconnects 218(2). For example, the second interconnect bumps 240 may be solder bumps that form a solder joint between the first RDL interconnects 236(1) and the second metal interconnects 218(2). The second interconnect bumps 240 could also be ball grid array (BGA) interconnects as another example. The second interconnect bumps 240 may be disposed in openings 244 formed in a solder resist layer 246 adjacent to the first RDL 234(1) in the second, vertical direction (Z-axis direction). Also in this example, the first metallization layer 220(1) includes third interconnect bumps 242 that are formed on the die interconnects 222 or first metal interconnects 218(1) to couple the die interconnects 222 to the first metal interconnects 218(1). For example, the third interconnect bumps 242 may be solder bumps that form a solder joint between the die interconnects 222 to the first metal interconnects 218(1). The third interconnect bumps 242 could also be ball grid array (BGA) interconnects as another example.

As discussed in more detail below, by providing the RDL substrate 230, the connections between the capacitor terminals 210 of the silicon capacitor 204 and the die interconnects 222 of the die 208 can be aligned. In this regard, the second RDL interconnects 236(2) can be formed in the second RDL 234(2) of the RDL substrate 230 to be aligned with the capacitor terminal 210 and the second metal interconnects 218(2) of the second metallization layer 220(2). In this example, the second RDL interconnects 236(2) in the second RDL 234(2) of the RDL substrate 230 have a second, longitudinal axis LA₂ in the second, vertical direction (Z-axis direction) that intersects a respective capacitor terminal 210. The first RDL interconnects 236(1) can be formed in the first RDL 234(1) of the RDL substrate 230 to be aligned with the first metal interconnects 218(1) in the first metallization layer 220(1) and the die interconnects 222. In this example, the first RDL interconnects 236(1) in the first RDL 234(1) of the RDL substrate 230 have a first, longitudinal axis LA₁ in the second, vertical direction (Z-axis direction) that intersects a respective first metal interconnect 218(1) and die interconnect 222. In this manner, the RDL substrate 230 facilitates the re-distribution of connections from the capacitor terminals 210 of the silicon capacitor 204 to the die interconnects 222 of the die 208 in the first, horizontal direction (X-axis and/or Y-axis direction(s)) to reduce the signal path length between the silicon capacitor 204 and the die 208.

To illustrate one example of how the RDL substrate 230 aligns connections between the die interconnects 222 and the capacitor terminals 210 of the capacitor 232 in the IC package 200 in FIGS. 2A and 2B, FIGS. 2C-2E are provided. FIGS. 2C-2E are respective top views of exemplary capacitor terminals 210 of the capacitor 232 (FIG. 2C), the first RDL interconnects 236(1) of the first RDL 234(1) of the RDL substrate 230 of the capacitor package 228 (FIG. 2D), and the die interconnects 222 of the die 208 (FIG. 2E) in the IC package 200 of FIGS. 2A and 2B. As shown in FIG. 2C, the capacitor terminals 210 of the silicon capacitor 204 have a first alignment and minimum second pitches P₅, P₆ in the respective first, horizontal directions (X-axis and Y-axis directions). However, as shown in FIG. 2E, the die interconnects 222 of the die 208 are not aligned with the capacitor terminals 210 of the silicon capacitor 204 in both first, horizontal directions (X-axis and Y-axis directions). Thus, if the die interconnects 222 were directly coupled to interconnects that were aligned with the capacitor terminals 210, the die interconnects 222 would not be aligned with the capacitor terminals 210, thus requiring entangled signal routing in the package substrate 202. For example, certain die interconnects 222 have smaller first pitches P₇, P₈ in both first, horizontal directions (X-axis and Y-axis directions) than the minimum second pitches P₅, P₆ of the closest aligned capacitor terminals 210 in the second, vertical direction (Z-axis direction) in the event that the die interconnects 222 have a smaller pitch than the capacitor terminals 210.

However, in this example, as shown in FIG. 2D, the first RDL 234(1) of the RDL substrate 230 has first RDL interconnects 236(1) that are aligned in the first, horizontal directions (X-axis and Y-axis directions) with the die interconnects 222. The first RDL interconnects 236(1) have the same pitches P₇, P₈ in both first, horizontal directions (X-axis and Y-axis directions) as the die interconnects 222. This provides an aligned connection between the RDL substrate 230 and the die interconnects 222 through the first metallization layer 220(1). The first metallization layer 220(1) can be patterned like the first RDL interconnects 236(1) in FIG. 2D. However, the second RDL 234(2) in the RDL substrate 230 can have second RDL interconnects 236(2) that are patterned like the capacitor terminals 210 shown in FIG. 2C to be aligned with the capacitor terminals 210. In this regard, the RDL substrate 230 redistributes the connections between the capacitor terminals 210 and the first metal interconnects 218(1) to provide greater alignment between the connections of the capacitor terminals 210 and the die interconnects 222 to reduce signal routing paths between the die 208 and the silicon capacitor 204. For example, the first pitches P₇, P₈ may be 130 micrometers (μm) and smaller than the second pitches P₅, P₆ which may be 150 micrometers (μm).

However, the RDL substrate 230 could be also designed to align connections of the capacitor terminals 210 of the capacitor 232 having a smaller pitch than the pitch of the die interconnects 222. This is shown by example in FIGS. 2F-2H. As shown in FIG. 2F, the capacitor terminals 210 of the silicon capacitor 204 can have a first alignment and second pitches P₇, P₈ in the respective first, horizontal directions (X-axis and Y-axis directions). However, as shown in FIG. 2H, the die interconnects 222 of the die 208 are not aligned with the capacitor terminals 210 of the silicon capacitor 204 in both first, horizontal directions (X-axis and Y-axis directions), ad have a larger first minimum pitch P₅, P₆. For example, certain die interconnects 222 have larger minimum first pitches P₅, P₆ in both first, horizontal directions (X-axis and Y-axis directions) than the second pitches P₇, P₈ of the closest aligned capacitor terminals 210 in the second, vertical direction (Z-axis direction) in the event that the die interconnects 222 have a larger pitch than the capacitor terminals 210.

In this example, as shown in FIG. 2G, the second RDL 234(2) of the RDL substrate 230 has second RDL interconnects 236(2) that are aligned in the first, horizontal directions (X-axis and Y-axis directions) with the capacitor terminals 210. The second RDL interconnects 236(2) have the same pitches P₇, P₈ in both first, horizontal directions (X-axis and Y-axis directions) as the capacitor terminals 210. This provides an aligned connection between the RDL substrate 230 and the capacitor terminals 210 through the second metallization layer 220(2). However, the first RDL 234(1) in the RDL substrate 230 can have first RDL interconnects 236(1) that are patterned like the die interconnects 222 shown in FIG. 2H to be aligned with the die interconnects 222. In this regard, the RDL substrate 230 redistributes the connections between the capacitor terminals 210 and the first metal interconnects 218(1) to provide greater alignment between the connections of the capacitor terminals 210 and the die interconnects 222 to reduce signal routing paths between the die 208 and the silicon capacitor 204.

Note that in the IC package 200 in FIGS. 2A and 2B, the RDL substrate 230 could be formed to only include one RDL 234(1) that has RDL interconnects 236(1) coupled to the capacitor terminals 210 and the second metal interconnects 218(2) of the second metallization layer 220(2). Also in the IC package 200 in FIGS. 2A and 2B, the package substrate 202 could only include one metallization layer 220(1) coupling the RDL substrate 230 to the die interconnects 222 of the die 208 to couple the capacitor terminals 210 to the die interconnects 222 of the die 208.

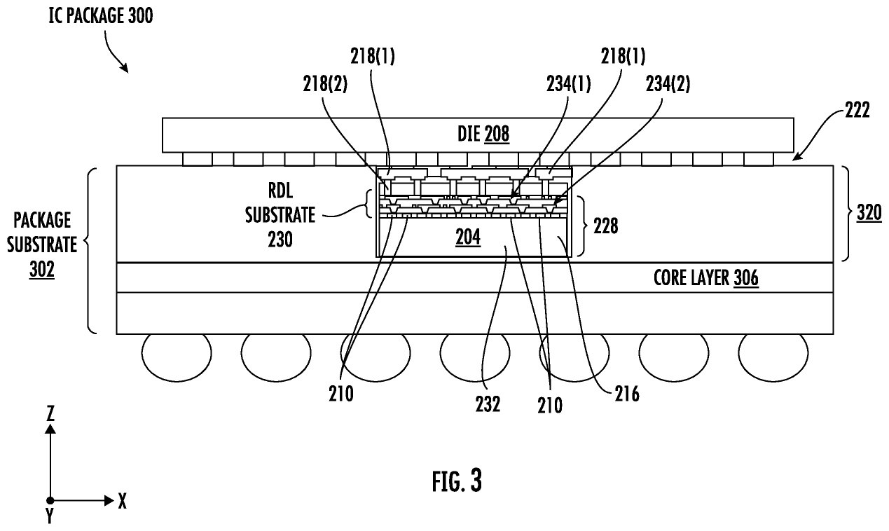

FIG. 3 is a side view of another exemplary IC package 300 that also includes a cored package substrate 302 with a core layer 306 and with an embedded capacitor package 228 like in the IC package 200 in FIGS. 2A and 2B. However, in the IC package 300 in FIG. 3, the capacitor package 228 is embedded in metallization layers 320 of the package substrate 302 instead of the core layer 306. Common elements between the IC package 300 in FIG. 3 and the IC package 200 in FIGS. 2A and 2B are shown with the same element numbers.

FIG. 4 is side view of another exemplary IC package 400 that includes a coreless package substrate 402 having an embedded capacitor package 228 like in the IC package 200 in FIGS. 2A and 2B. However, in the IC package 400 in FIG. 4, the capacitor package 228 is embedded in metallization layers 420 that do not include a core layer. Common elements between the IC package 400 in FIG. 4 and the IC package 200 in FIGS. 2A and 2B are shown with the same element numbers.

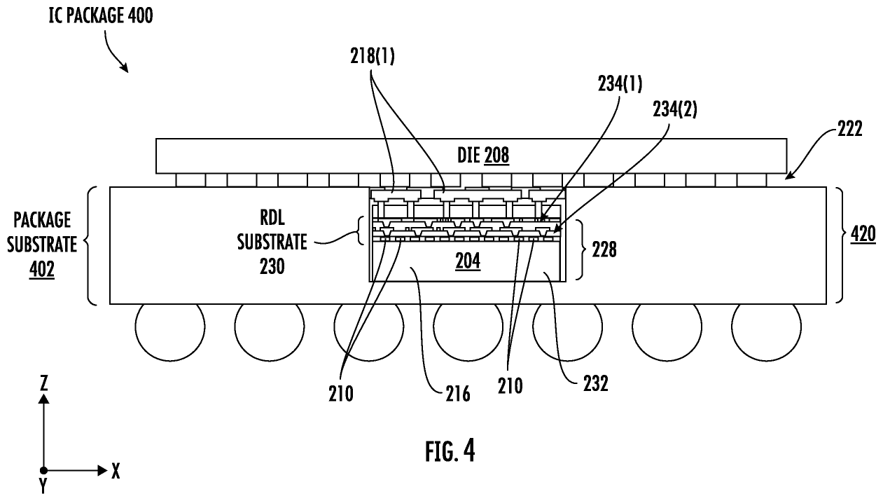

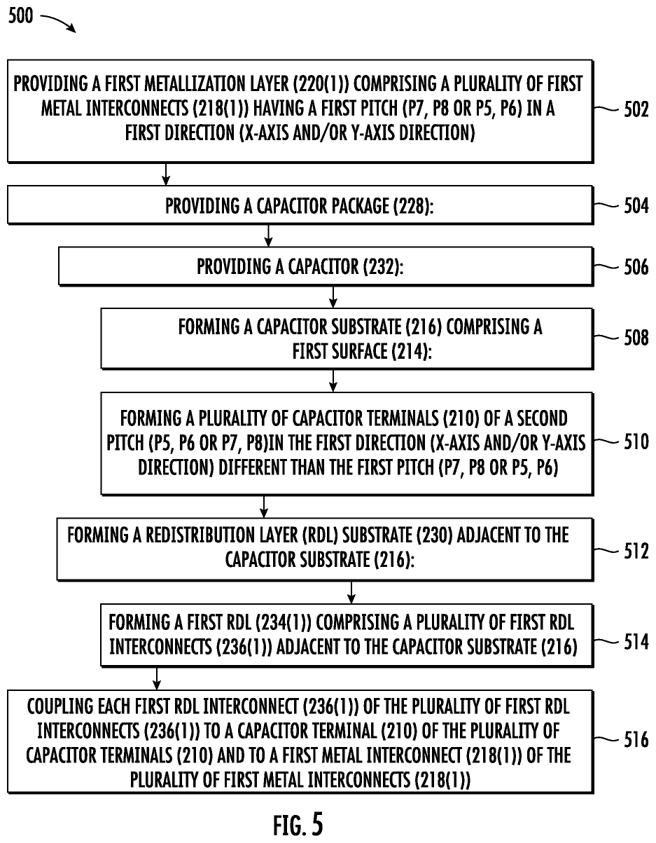

Package substrates that have an embedded capacitor package(s) that include a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the connection path length between the capacitor and the die can be fabricated according to a fabrication process. In this regard, FIG. 5 is a flowchart illustrating an exemplary fabrication process 500 of fabricating a package substrate, including, but not limited to, the package substrates 202, 302, 402 in FIGS. 2A-4, that have an embedded capacitor package(s), including, but not limited to, the capacitor packages 228 in FIGS. 2A-4, wherein the capacitor package includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the connection path length between the capacitor and the die. The fabrication process 500 in FIG. 5 is discussed in reference to the package substrate 202 and embedded capacitor package 228 in the IC package 200 in FIGS. 2A-2B, but the fabrication process 500 is not limited to such.

In this regard, as shown in FIG. 5, the fabrication process 500 of fabricating the package substrate 202 can include providing a first metallization layer 220(1) comprising a plurality of first metal interconnects 218(1) having a first pitch P₇, P₈ or P₅, P₆ in a first direction (X-axis and/or Y-axis direction) (block 502 in FIG. 5). The fabrication process 500 can also include providing a capacitor package 228 (block 504 in FIG. 5) that includes providing a capacitor 232 (block 506 in FIG. 5) comprising forming a capacitor substrate 216 comprising a first surface 214 (block 508 in FIG. 5) and forming a plurality of capacitor terminals 210 of a second pitch P₅, P₆ or P₇, P₈ in the first direction (X-axis and/or Y-axis direction) different than the first pitch P₇, P₈ or P₅, P₆ (block 510 in FIG. 5). The fabrication process 500 can also include forming a RDL substrate 230 adjacent to the capacitor substrate 216 (block 512 in FIG. 5), comprising forming a first RDL 234(1) comprising a plurality of first RDL interconnects 236(1) adjacent to the capacitor substrate 216 (block 514 in FIG. 5), and coupling each first RDL interconnect 236(1) of the plurality of first RDL interconnects 236(1) to a capacitor terminal 210 of the plurality of capacitor terminals 210 and to a first metal interconnect 218(1) of the plurality of first metal interconnects 218(1) (block 516 in FIG. 5).

A package substrate, including, but not limited to, the package substrates 202, 302, 402 in FIGS. 2A-4, that have an embedded capacitor package(s), including, but not limited to, the capacitor packages 228 in FIGS. 2A-4, wherein the capacitor package includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the connection path length between the capacitor and the die, can be fabricated in other fabrication processes.

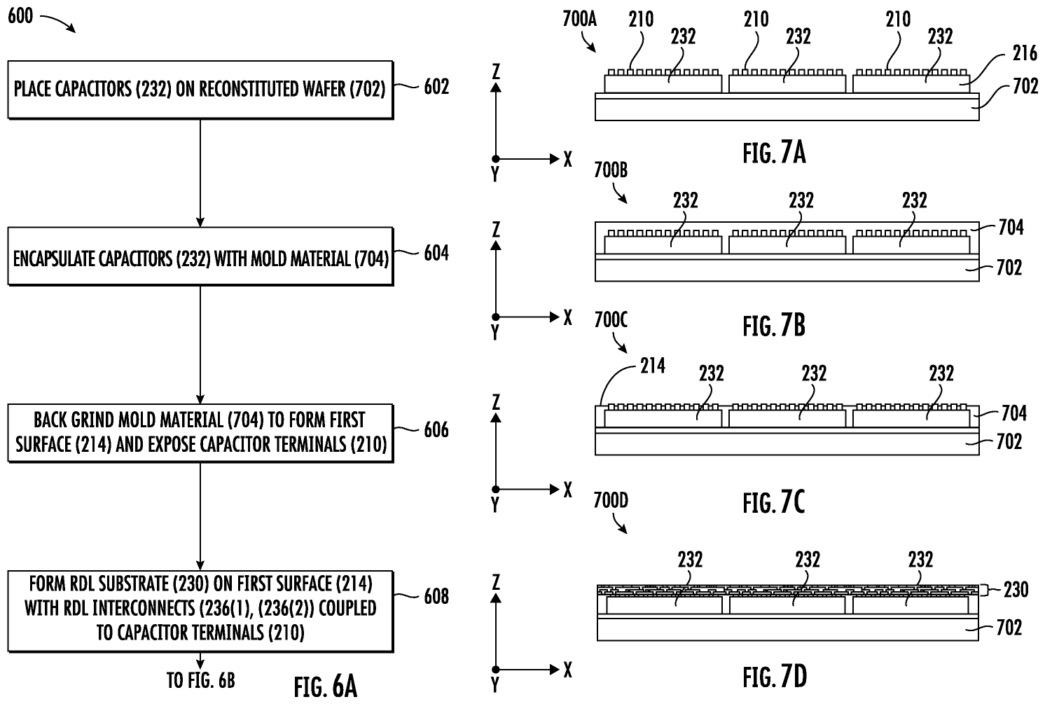

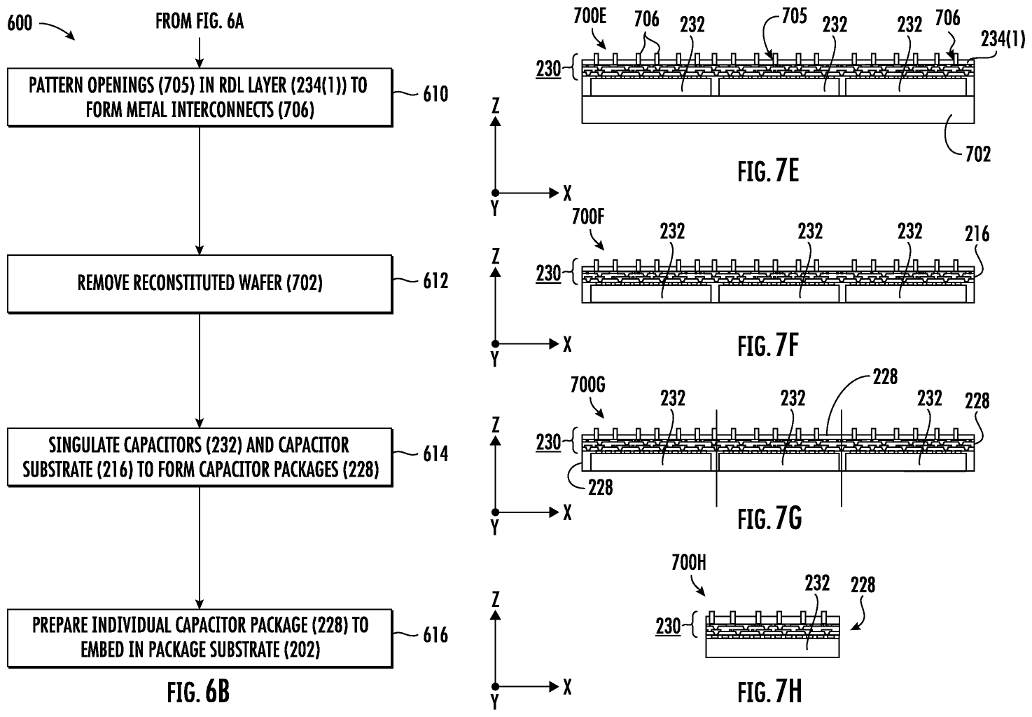

For example, FIGS. 6A and 6B is a flowchart illustrating a fabrication process 600 of fabricating capacitor packages that each include a RDL(s) formed on a substrate of a capacitor with RDL interconnects of the RDL(s) coupled to capacitor terminals of the capacitor to redistribute the connections to the capacitor terminals, such that the capacitor package can be provided in an IC package with the capacitor terminals of the capacitor aligned with die interconnects of a die coupled to the package substrate of the IC package to minimize the connection path length between the capacitor and the die, including, but not limited to, the capacitor packages 228 in FIGS. 2A-4. FIGS. 7A-7H are exemplary fabrication stages 700A-700H during fabrication of the capacitor packages according to the exemplary fabrication process 600 in FIGS. 6A and 6B. The fabrication process 600 in FIGS. 6A and 6B is discussed below with reference to the exemplary capacitor package 228 in the IC package 200 in FIGS. 2A and 2B that is fabricated as multiple capacitor packages according to a reconstituted wafer fabrication process, but such is not limiting.

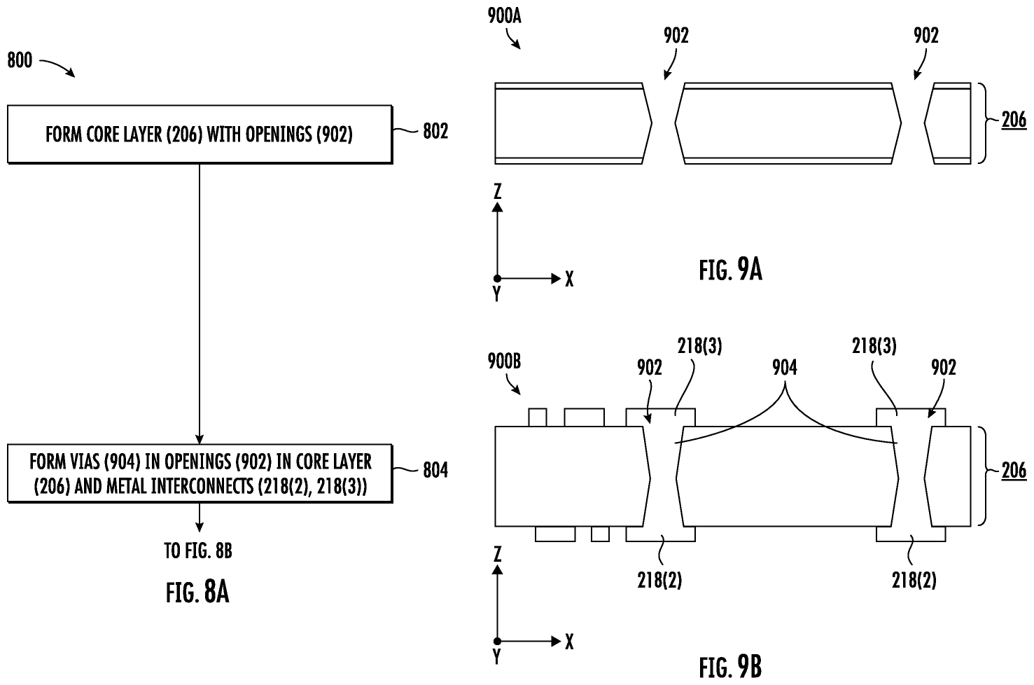

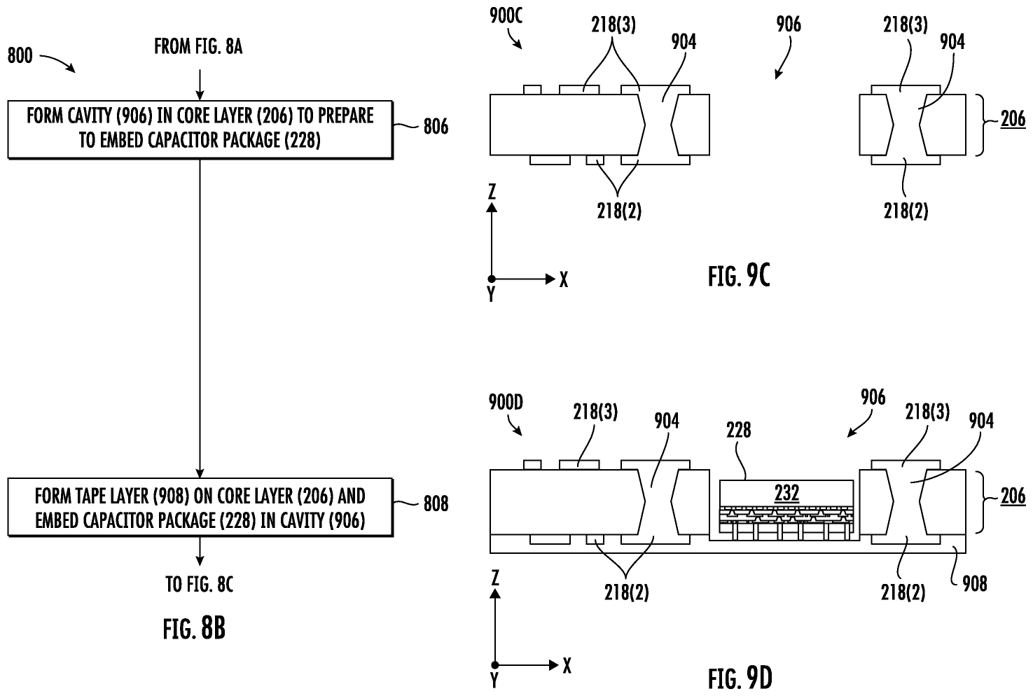

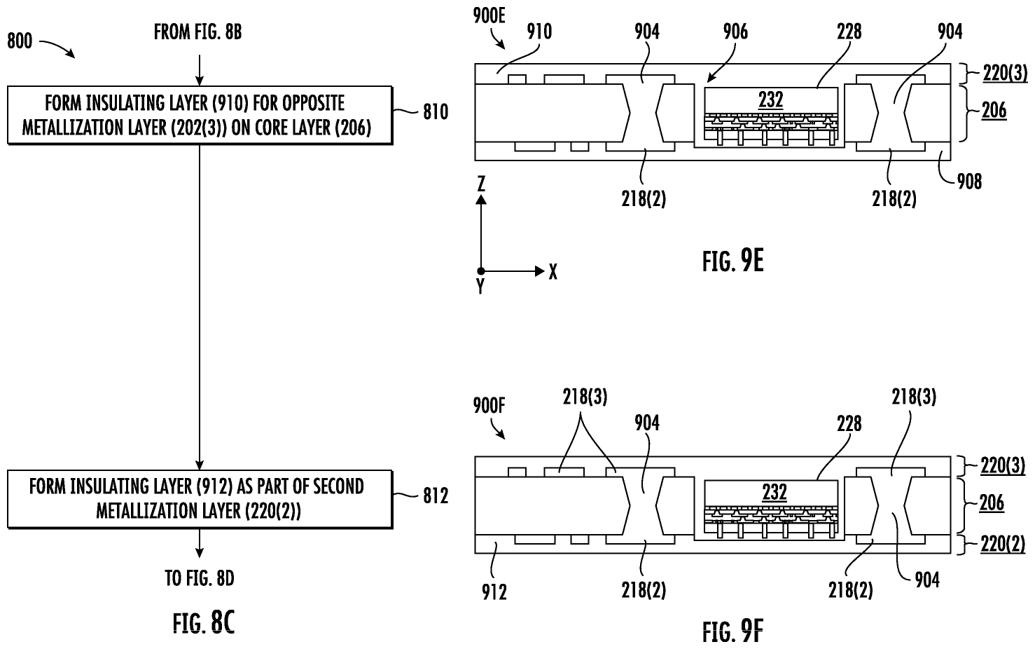

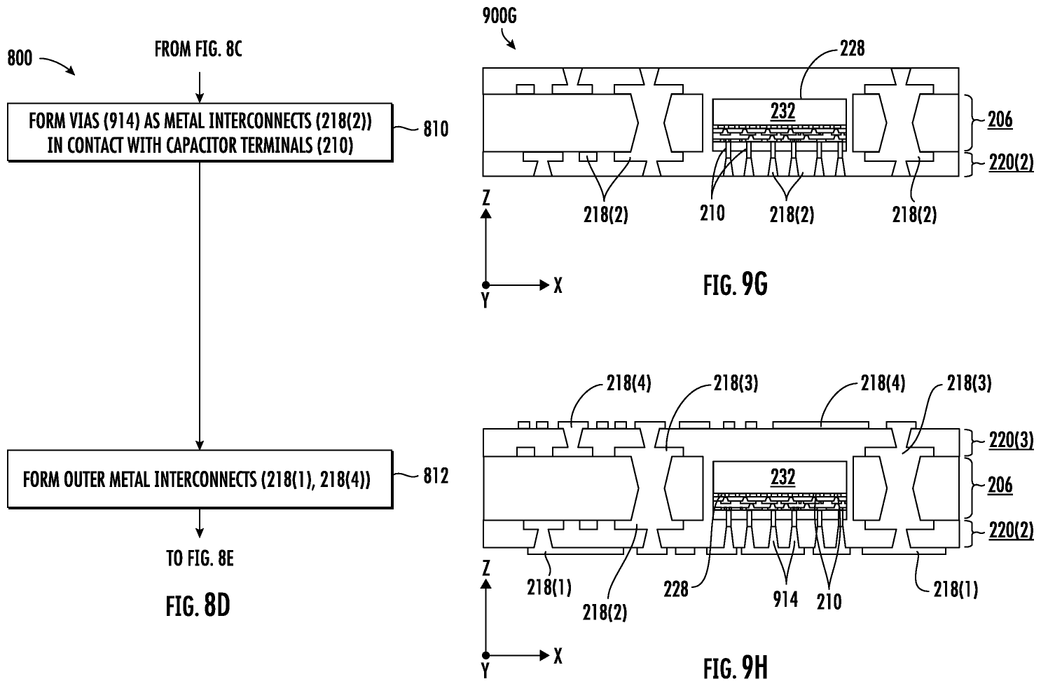

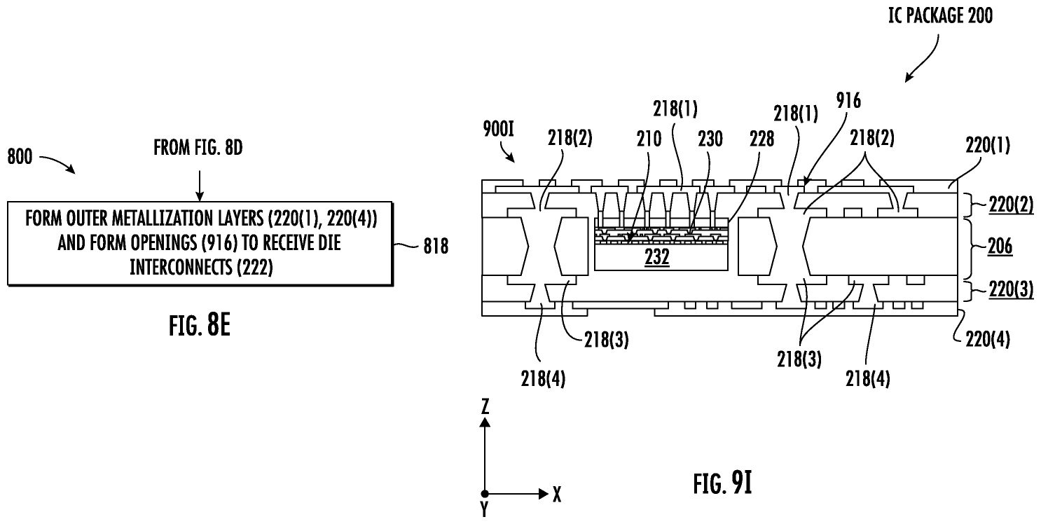

In this regard, as shown in the exemplary fabrication stage 700A in FIG. 7A, a first step in the fabrication process 600 can be placing silicon capacitors 204 on a reconstituted wafer 702 (block 602 in FIG. 6A). The silicon capacitors 204 can be fabricated employing another silicon capacitor fabrication process. The silicon capacitors 204 each include a capacitor substrate 216 in which the capacitors are formed. Multiple silicon capacitors 204 can be placed on a reconstituted wafer 702 so that RDL substrates 230 can be formed thereon in contact with their capacitor terminals 210 to form multiple capacitor packages 228, which can then be later diced to provide multiple individual capacitor packages 228. Those capacitor packages 228 can then be embedded in a package substrate 202 as part of a package substrate fabrication process, as will be discussed by example in FIGS. 8A-8E below.

Then, as shown in the exemplary fabrication stage 700B in FIG. 7B, a next step in the fabrication process 600 can be encapsulating the silicon capacitors 204 placed on the reconstituted wafer 702 with a mold material 704 (block 604 in FIG. 6A). This is to protect the silicon capacitors 204 and their capacitor terminals 210 and insulate the capacitor terminals 210 from each other to prepare for further processing. Then, as shown in the exemplary fabrication stage 700C in FIG. 7C, a next step in the fabrication process 600 can be back grinding the mold material 704 to the first surface 214 of the capacitor substrate 216 and exposing the capacitor terminals 210 (block 606 in FIG. 6A). Then, as shown in the exemplary fabrication stage 700D in FIG. 7D, a next step in the fabrication process 600 can be forming the RDL substrate 230 on the first surface 214 of the mold material 704 which will become part of the capacitor packages 228 (block 608 in FIG. 6A). The RDL substrate 230 can be formed by building up one or more RDLs 234(1), 234(2) that each have RDL interconnects 236(1), 236(2) as previously described with regard to FIGS. 2A and 2B. The process of forming the RDLs 234(1), 234(4) can be to provide a coating layer to expose and pattern openings for the designed redistribution of signal routing paths and to form the RDL interconnects 236(1), 236(2) with an under bump metallization (UBM) process.

Then, shown in the exemplary fabrication stage 700E in FIG. 7E, a next step in the fabrication process 600 can be patterning openings 705 in the RDL 234(1) of the RDL substrate 230 to prepare for metal plating to form metal interconnects 706 (e.g., copper pillars) that will serve to couple the RDL substrate 230 to the second metallization layer 220(2) (block 610 in FIG. 6B). The combined RDL substrates 230 and silicon capacitors 204 will form the capacitor packages 228 after dicing. Then, as shown in the exemplary fabrication stage 700F in FIG. 7F, a next step in the fabrication process 600 can be to remove the reconstituted wafer 702 to prepare for dicing to prepare the individual capacitor substrates 216 (block 612 in FIG. 6B). Then, as shown in the exemplary fabrication stage 700G in FIG. 7G, a next step in the fabrication process 600 is to dice or singulate the capacitor substrates 216 to provide individual capacitor packages 228 (block 614 in FIG. 6B). This provides individual capacitor substrate 228 that can be embedded in a package substrate 202, as shown in fabrication stage 700H in FIG. 7H (block 616 in FIG. 6B).

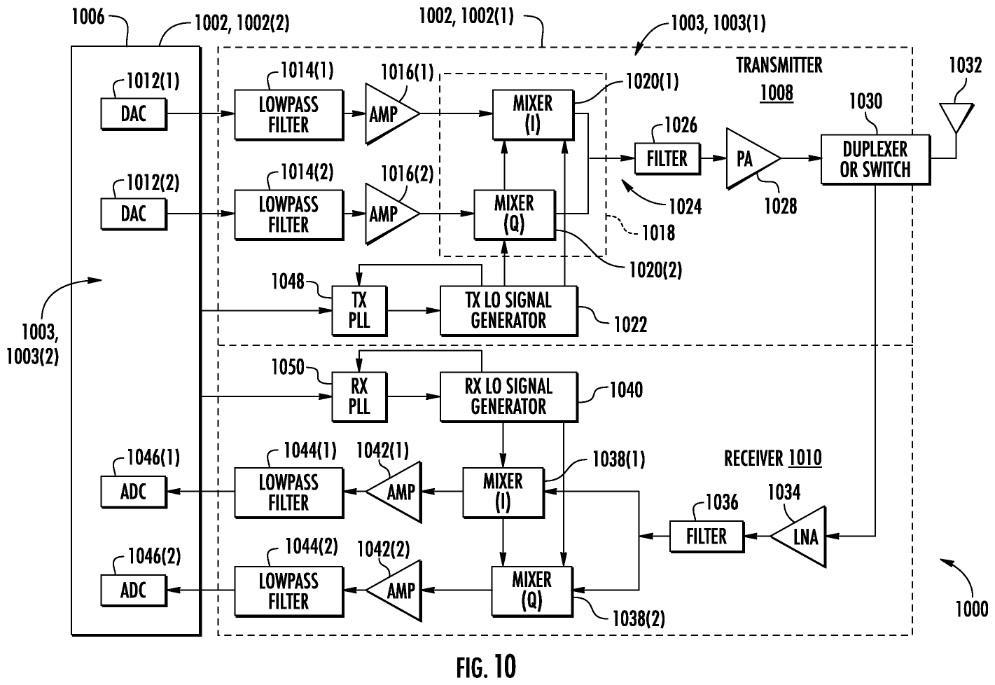

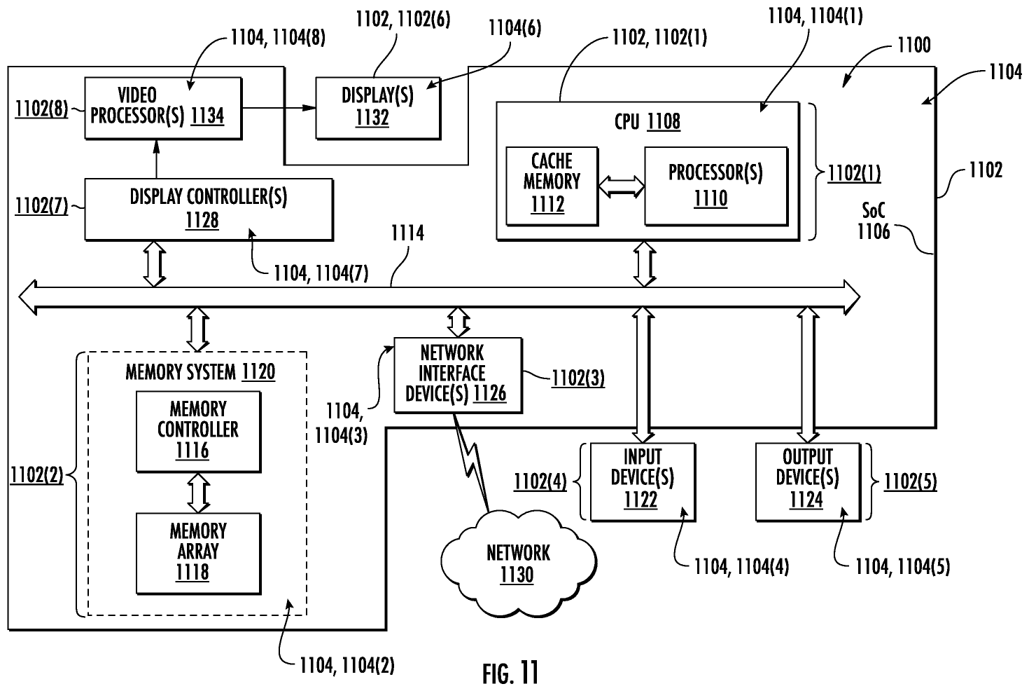

FIGS. 8A-8E is a flowchart illustrating another fabrication process 800 for fabricating a package substrate that includes an embedded capacitor package that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in an IC package to minimize the connection path length between the capacitor and the die, including, but not limited to, the package substrates 202, 302, 402 in FIGS. 2A-4. FIGS. 9A-9I are exemplary fabrication stages 900A-900I during fabrication of the package substrate according to the exemplary fabrication process 800 in FIGS. 8A-8E. The fabrication process 800 in FIGS. 8A-8E can be performed using capacitor packages fabricated using the fabrication process 600 in FIGS. 6A and 6B as an example. The fabrication process 800 in FIGS. 8A-8E is discussed below with reference to the exemplary package substrate 202 in the IC package 200 in FIGS. 2A and 2B, but such is not limiting.

In this regard, as shown in the exemplary fabrication stage 900A in FIG. 9A, a first step in the fabrication process 800 can be to form the core layer 206 since this example involves fabricating the package substrate 202 that includes the core layer 206 (block 802 in FIG. 8A). For example, the core layer 206 can be made of a stiffer material that is between forty (40) and two-hundred (200) μm. Openings 902 are formed in the core layer 206 to allow for via formation to provide connective coupling through the core layer 206. Then, as shown in the exemplary fabrication stage 900B in FIG. 9B, a next step in the fabrication process 800 can be to form vias 904 in the openings 902 and metal interconnects 218(2), 218(3) that provide interconnects for electrical coupling to the vias 904 (block 804 in FIG. 8B). Then, as shown in the exemplary fabrication stage 900C in FIG. 9C, a next step in the fabrication process 800 can be to form a cavity 906 in the core layer 206 to prepare for embedding a capacitor package 228 in the core layer 206 (block 806 in FIG. 8C). Then, as shown in the exemplary fabrication stage 900D in FIG. 9D, a next step in the fabrication process 800 can be to form a tape layer 908 then embed the capacitor package 228 in the cavity 906 (block 808 in FIG. 8D). The capacitor package 228 is coupled to the tape layer 908 to temporarily retain the capacitor package 228 in the cavity 906.

Then, as shown in the exemplary fabrication stage 900E in FIG. 9E, a next step in the fabrication process 800 can be to form an insulating layer 910 on the core layer 206 on the opposite side of the metallization layer 220(3) to insulate the metal interconnects 218(3) (block 810 in FIG. 8C). Then, as shown in the exemplary fabrication stage 900F in FIG. 9F, a next step in the fabrication process 800 can be to form an insulating layer 912 on the core layer 206 that insulates the second metal interconnects 218(2) and that will be part of the second metallization layer 220(2) of the package substrate 202 (block 812 in FIG. 8C). Then, as shown in the exemplary fabrication stage 900G in FIG. 9G, a next step in the fabrication process 800 can be to form vias 914 that are a form of second metal interconnects 218(2) in the second metallization layer 220(2) and that are coupled to the capacitor terminals 210 of the capacitor package 228 (block 814 in FIG. 8D).

Then, as shown in the exemplary fabrication stage 900H in FIG. 9H, a next step in the fabrication process 800 can be to form the metal interconnects 218(1), 218(4) that will be part of the outer metallization layer to provide metal interconnects for coupling to the capacitor package 228 (block 816 in FIG. 8D). Then, as shown in the exemplary fabrication stage 900I in FIG. 9I, a next step in the fabrication process 800 can be to form outer metallization layers 220(1), 220(4) with openings 916 exposing the first metal interconnects 218(1) to allow die interconnects 222 of a die 208 to be coupled to the first metal interconnects 218(1) to provide an electrical coupling to the capacitor package 228 (block 818 in FIG. 8E).

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Capacitor packages that include a RDL(s) formed on a substrate of the capacitor, with RDL interconnects of the RDL(s) coupled to capacitor terminals of a capacitor to redistribute the connections to the capacitor terminals to be aligned with die interconnects of a die coupled to the substrate of an IC package to minimize the signal path length between the capacitor and the die, including, but not limited to, the capacitor packages 228 in FIGS. 2A-4 and 7H, and IC packages that include such capacitor packages, including, but not limited to, the IC packages 200, 300, 400 in FIGS. 2A-2B, 3, 4, and 9I, and that can be fabricated according to a fabrication process, including, but not limited to, the exemplary fabrication processes 500, 600, 800 in FIGS. 5, 6A-6B and 8A-8E, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

In this regard, FIG. 10 illustrates an exemplary wireless communications device 1000 that includes one or more IC packages 1002, 1002(1), 1002(2), including but not limited to the IC packages 200, 300, 400 in FIGS. 2A-4 and 9I, that each include a package substrate with an embedded capacitor package(s) 1003, 1003(1), 1003(2), including, but not limited to, the capacitor packages 228 in FIGS. 2A-4, 7H, and 9I, that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the signal path length between the capacitor and the die, and that can be fabricated according to a fabrication process, including, but not limited to, the exemplary fabrication processes 500, 600, 800 in FIGS. 5, 6A-6B, and 8A-8E, and according to any aspects disclosed herein.

The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency upconversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Downconversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency upconversion, while the RX LO signal generator 1040 generates the I and Q RX LO signals used for frequency downconversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

FIG. 11 illustrates an example of a processor-based system 1100 that includes one or more IC packages 1102, 1102(1)-1102(8) including, but not limited to the IC packages 200, 300, 400 in FIGS. 2A-4 and 9I, that each include a package substrate with an embedded capacitor package(s) 1104, 1104(1)-1104(8), including, but not limited to, the capacitor packages 228 in FIGS. 2A-4, 7H, and 9I, that includes a RDL(s) formed on a substrate of a capacitor with RDL interconnects of the RDL(s) coupled to capacitor terminals of the capacitor to redistribute the connections to the capacitor terminals to be aligned with die interconnects of a die coupled to the package substrate in the IC package, to minimize the signal path length between the capacitor and the die, and that can be fabricated according to a fabrication process, including, but not limited to, the exemplary fabrication processes 500, 600, 800 in FIGS. 5, 6A-6B, and 8A-8E, and according to any aspects disclosed herein, and according to any aspects disclosed herein.

In this example, the processor-based system 1100 may include a capacitor package(s) 1104 that is included in an IC package 1102, such as a system-on-a-chip (SoC) 1106. The processor-based system 1100 includes a CPU 1108 that includes one or more processors 1110, which may also be referred to as CPU cores or processor cores. The CPU 1108 can be provided in an IC package 1102(1) that includes a package substrate with the embedded capacitor package 1104(1). The CPU 1108 may have cache memory 1112 coupled to the CPU 1108 for rapid access to temporarily stored data. The CPU 1108 is coupled to a system bus 1114 and can intercouple master and slave devices included in the processor-based system 1100. As is well known, the CPU 1108 communicates with these other devices by exchanging address, control, and data information over the system bus 1114. For example, the CPU 1108 can communicate bus transaction requests to a memory controller 1116 as an example of a slave device. Although not illustrated in FIG. 11, multiple system buses 1114 could be provided, wherein each system bus 1114 constitutes a different fabric.

Other master and slave devices can be connected to the system bus 1114. As illustrated in FIG. 11, these devices can include a memory system 1120 that includes the memory controller 1116 and a memory array(s) 1118, one or more input devices 1122, one or more output devices 1124, one or more network interface devices 1126, and one or more display controllers 1128, as examples. The memory system 1120 can be provided in an IC package 1102(2) that includes a package substrate with the embedded capacitor package 1104(2). The network interface devices 1126 can be provided in an IC package 1102(3) that includes a package substrate with the embedded capacitor package 1104(3). Each of the memory system 1120, the one or more input devices 1122, the one or more output devices 1124, the one or more network interface devices 1126, and the one or more display controllers 1128 can be provided in the same or different circuit packages. The input devices 1122 and/or the output devices 1124 can be provided in a respective IC package 1102(4), 1102(5) that includes a package substrate with a respective embedded capacitor package 1104(4), 1104(5). The input device(s) 1122 can include any type of input device, including, but not limited to, input keys, switches, voice processors, etc. The output device(s) 1124 can include any type of output device, including, but not limited to, audio, video, other visual indicators, etc. The network interface device(s) 1126 can be any device configured to allow exchange of data to and from a network 1130. The network 1130 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1126 can be configured to support any type of communications protocol desired.

The CPU 1108 may also be configured to access the display controller(s) 1128 over the system bus 1114 to control information sent to one or more displays 1132. The display 1132 can be provided in an IC package 1102(6) that includes a package substrate with the embedded capacitor package 1104(6). The display controller(s) 1128 sends information to the display(s) 1132 to be displayed via one or more video processors 1134, which process the information to be displayed into a format suitable for the display(s) 1132. The display controller(s) 1128 and video processor(s) 1134 can be provided in a respective IC package 1102(7), 1102(8) that includes a package substrate with a respective embedded capacitor package 1104(7), 1104(8), or be provided in the same IC package 1102, or be provided in the same IC package 1102(1) containing the CPU 1108 as an example. The display(s) 1132 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A package substrate, comprising:
   a first metallization layer comprising a plurality of first metal interconnects having a first pitch in a first direction;
   a capacitor package, comprising:
      a capacitor, comprising:
         a capacitor substrate comprising a first surface; and
         a plurality of capacitor terminals having a second pitch in the first direction different than the first pitch; and
      a redistribution layer (RDL) substrate adjacent to the capacitor substrate,
         the RDL substrate comprising:
         a first RDL comprising a plurality of first RDL interconnects each coupled to a capacitor terminal of the plurality of capacitor terminals and each coupled to a first metal interconnect of the plurality of first metal interconnects.
2. The package substrate of clause 1, wherein the first pitch is smaller than the second pitch.
3. The package substrate of clause 2, wherein the first pitch is 130 micrometers (μm) and the second pitch is 150 μm.
4. The package substrate of clause 1, wherein the first pitch is larger than the second pitch.
5. The package substrate of clause 4, wherein each first RDL interconnect of the plurality of first RDL interconnects has a first axis intersecting the first metal interconnect in a second direction orthogonal to the first direction.
6. The package substrate of any of clauses 1-5, wherein the RDL substrate further comprises a second RDL comprising a plurality of second RDL interconnects each coupled to a capacitor interconnect of the plurality of capacitor interconnects and to a first RDL interconnect of the plurality of first RDL interconnects.
7. The package substrate of clause 6, wherein each second RDL interconnect of the plurality of second RDL interconnects has a second axis intersecting a capacitor terminal of the plurality of capacitor terminals in a second direction orthogonal to the first direction.
8. The package substrate of any of clauses 1-7, wherein the plurality of capacitor terminals comprises a plurality of first interconnect bumps.
9. The package substrate of clause 8, wherein the RDL substrate further comprises a plurality of second interconnect bumps each coupled to a first interconnect bump of the plurality of first interconnect bumps and each coupled to a first metal interconnect of the plurality of first metal interconnects.
10. The package substrate of clause 9, wherein:
   the RDL substrate further comprises a solder resist layer adjacent to the first RDL in a second direction orthogonal to the first direction, the solder resist layer comprising a plurality of openings; and
   each second interconnect bump of the plurality of second interconnect bumps is at least partially disposed in an opening of the plurality of openings and coupled to a first RDL interconnect of the plurality of first RDL interconnects.
11. The package substrate of clause 9 or 10, wherein the package substrate further comprises a plurality of third interconnect bumps adjacent to the first metallization layer, each third interconnect bump of the plurality of third interconnect bumps coupled to a second interconnect bump of the plurality of second interconnect bumps.
12. The package substrate of any of clauses 1-11, wherein:
   the package substrate comprises a cored package substrate comprising a core layer adjacent to the first metallization layer in a second direction orthogonal to the first direction; and
   the capacitor package is at least partially embedded in the core layer.
13. The package substrate of any of clauses 1-11, wherein the package substrate comprises a coreless package substrate.
14. The package substrate of any of clauses 1-11 and 13, wherein the package substrate is at least partially embedded in the first metallization layer.
15. The package substrate of any of clauses 1-14, wherein the capacitor comprises a silicon capacitor.
16. The package substrate of any of clauses 1-15 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
17. A method of fabricating a package substrate, comprising:
   providing a first metallization layer comprising a plurality of first metal interconnects having a first pitch in a first direction; and
   providing a capacitor package, comprising:
      providing a capacitor, comprising:
         forming a capacitor substrate comprising a first surface; and
         forming a plurality of capacitor terminals having a second pitch in the first direction different than the first pitch; and
   forming a redistribution layer (RDL) substrate adjacent to the capacitor substrate, comprising:
      forming a first RDL comprising a plurality of first RDL interconnects adjacent to the capacitor substrate; and
   coupling each first RDL interconnect of the plurality of first RDL interconnects to a capacitor terminal of the plurality of capacitor terminals and to a first metal interconnect of the plurality of first metal interconnects.
18. The method of clause 17, wherein the first pitch is smaller than the second pitch.
19. The method of clause 17, wherein the first pitch is larger than the second pitch.
20. The package substrate of any of clauses 17-19, wherein forming the RDL substrate further comprises:
   forming second RDL comprising a plurality of second RDL interconnects adjacent to the first RDL in a second direction orthogonal to the first direction; and
   coupling each second RDL interconnects of the plurality of second RDL interconnects to a capacitor interconnect of the plurality of capacitor interconnects and to a first RDL interconnect of the plurality of first RDL interconnects.
21. The method of any of clauses 17-20, further comprising:
   forming a core layer adjacent to the first metallization layer in a second direction orthogonal to the first direction; and
   at least partially embedding the capacitor package in the core layer.
22. The method of any of clauses 17-21, wherein:
   providing the capacitor package further comprises:
      disposing the capacitor on a wafer;
   forming the RDL substrate comprises forming the RDL substrate adjacent to the capacitor substrate on the wafer; and
   dicing the wafer to provide the capacitor substrate.
23. The method of any of clauses 17-22, further comprising:
   forming a cavity in the first metallization layer; and
   at least partially embedding the capacitor package in the cavity.
24 The method of any of clauses 17-22, further comprising:
   forming core layer adjacent to the first metallization layer in a second direction orthogonal to the first direction;
   forming a cavity in the core layer; and
   at least partially embedding the capacitor package in the cavity.
25. An integrated circuit (IC) package, comprising:
   a package substrate, comprising:
      a first metallization layer comprising a plurality of first metal interconnects having a first pitch in a first direction; and
      a capacitor package, comprising:
         a capacitor, comprising:
         a capacitor substrate comprising a first surface; and
         a plurality of capacitor terminals having a second pitch in the first direction different than the first pitch; and
         a redistribution layer (RDL) substrate adjacent to the capacitor substrate, the RDL substrate comprising:
         a first RDL comprising a plurality of first RDL interconnects each coupled to a capacitor terminal of the plurality of capacitor terminals and each coupled to a first metal interconnect of the plurality of first metal interconnects; and
   a die comprising a plurality of die interconnects having the first pitch in the first direction and each coupled to a first metal interconnect of the plurality of first metal interconnects.
26. The IC package of clause 25, wherein the first pitch is smaller than the second pitch.
27. The IC package of clause 25, wherein the first pitch is larger than the second pitch.
28. The IC package of any of clauses 25-27, wherein each first RDL interconnect of the plurality of first RDL interconnects has a first axis intersecting the first metal interconnect in a second direction orthogonal to the first direction.
29 The IC package of any of clauses 25-28, wherein:
   the package substrate comprises a cored package substrate comprising a core layer adjacent to the first metallization layer in a second direction orthogonal to the first direction; and
   the capacitor package is at least partially embedded in the core layer.
30. The IC package of any of clauses 25-28, wherein:
   the package substrate comprises a coreless package substrate; and
   the package substrate is at least partially embedded in the first metallization layer.

What is claimed is:

1. A package substrate, comprising:
a first metallization layer comprising a plurality of first metal interconnects having a first pitch in a first direction;
a capacitor package, comprising:
a capacitor, comprising:
a capacitor substrate comprising a first surface; and
a plurality of capacitor terminals having a second pitch in the first direction different than the first pitch; and
a redistribution layer (RDL) substrate adjacent to the capacitor substrate, the RDL substrate comprising:
a first RDL comprising a plurality of first RDL interconnects each coupled to a capacitor terminal of the plurality of capacitor terminals and each coupled to a first metal interconnect of the plurality of first metal interconnects.

2. The package substrate of claim 1, wherein the first pitch is smaller than the second pitch.

3. The package substrate of claim 2, wherein the first pitch is 130 micrometers (μm) and the second pitch is 150 μm.

4. The package substrate of claim 1, wherein the first pitch is larger than the second pitch.

5. The package substrate of claim 1, wherein each first RDL interconnect of the plurality of first RDL interconnects has a first axis intersecting the first metal interconnect in a second direction orthogonal to the first direction.

6. The package substrate of claim 1, wherein the RDL substrate further comprises a second RDL comprising a plurality of second RDL interconnects each coupled to a capacitor interconnect of the plurality of capacitor interconnects and to a first RDL interconnect of the plurality of first RDL interconnects.

7. The package substrate of claim 6, wherein each second RDL interconnect of the plurality of second RDL interconnects has a second axis intersecting a capacitor terminal of the plurality of capacitor terminals in a second direction orthogonal to the first direction.

8. The package substrate of claim 1, wherein the plurality of capacitor terminals comprises a plurality of first interconnect bumps.

9. The package substrate of claim 8, wherein the RDL substrate further comprises a plurality of second interconnect bumps each coupled to a first interconnect bump of the plurality of first interconnect bumps and each coupled to a first metal interconnect of the plurality of first metal interconnects.

10. The package substrate of claim 9, wherein:
the RDL substrate further comprises a solder resist layer adjacent to the first RDL in a second direction orthogonal to the first direction, the solder resist layer comprising a plurality of openings; and
each second interconnect bump of the plurality of second interconnect bumps is at least partially disposed in an opening of the plurality of openings and coupled to a first RDL interconnect of the plurality of first RDL interconnects.

11. The package substrate of claim 9, wherein the package substrate further comprises a plurality of third interconnect bumps adjacent to the first metallization layer, each third interconnect bump of the plurality of third interconnect bumps coupled to a second interconnect bump of the plurality of second interconnect bumps.

12. The package substrate of claim 1, wherein:
the package substrate comprises a cored package substrate comprising a core layer adjacent to the first metallization layer in a second direction orthogonal to the first direction; and
the capacitor package is at least partially embedded in the core layer.

13. The package substrate of claim 1, wherein the package substrate comprises a coreless package substrate.

14. The package substrate of claim 1, wherein the package substrate is at least partially embedded in the first metallization layer.

15. The package substrate of claim 1, wherein the capacitor comprises a silicon capacitor.

16. The package substrate of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio;
a music player; a digital music player; a portable music player; a digital video player; a video player; a digital video disc (DVD) player; a portable digital video player; an automobile; a vehicle component; an avionics system; a drone; and a multicopter.

17. A method of fabricating a package substrate, comprising:
providing a first metallization layer comprising a plurality of first metal interconnects having a first pitch in a first direction; and
providing a capacitor package, comprising:
providing a capacitor, comprising:
forming a capacitor substrate comprising a first surface; and
forming a plurality of capacitor terminals having a second pitch in the first direction different than the first pitch; and
forming a redistribution layer (RDL) substrate adjacent to the capacitor substrate, comprising:
forming a first RDL comprising a plurality of first RDL interconnects adjacent to the capacitor substrate; and
coupling each first RDL interconnect of the plurality of first RDL interconnects to a capacitor terminal of the plurality of capacitor terminals and to a first metal interconnect of the plurality of first metal interconnects.

18. The method of claim 17, wherein the first pitch is smaller than the second pitch.

19. The method of claim 17, wherein the first pitch is larger than the second pitch.

20. The package substrate of claim 17, wherein forming the RDL substrate further comprises:
forming second RDL comprising a plurality of second RDL interconnects adjacent to the first RDL in a second direction orthogonal to the first direction; and
coupling each second RDL interconnects of the plurality of second RDL interconnects to a capacitor interconnect of the plurality of capacitor interconnects and to a first RDL interconnect of the plurality of first RDL interconnects.

21. The method of claim 17, further comprising:
forming a core layer adjacent to the first metallization layer in a second direction orthogonal to the first direction; and
at least partially embedding the capacitor package in the core layer.

22. The method of claim 17, wherein:
providing the capacitor package further comprises:
disposing the capacitor on a wafer;
forming the RDL substrate comprises forming the RDL substrate adjacent to the capacitor substrate on the wafer; and
dicing the wafer to provide the capacitor substrate.

23. The method of claim 17, further comprising:
forming a cavity in the first metallization layer; and
at least partially embedding the capacitor package in the cavity.

24. The method of claim 17, further comprising:
forming core layer adjacent to the first metallization layer in a second direction orthogonal to the first direction;
forming a cavity in the core layer; and
at least partially embedding the capacitor package in the cavity.

25. An integrated circuit (IC) package, comprising:
a package substrate, comprising:
a first metallization layer comprising a plurality of first metal interconnects having a first pitch in a first direction; and
a capacitor package, comprising:
a capacitor, comprising:
a capacitor substrate comprising a first surface; and
a plurality of capacitor terminals having a second pitch in the first direction different than the first pitch; and
a redistribution layer (RDL) substrate adjacent to the capacitor substrate, the RDL substrate comprising:
a first RDL comprising a plurality of first RDL interconnects each coupled to a capacitor terminal of the plurality of capacitor terminals and each coupled to a first metal interconnect of the plurality of first metal interconnects; and
a die comprising a plurality of die interconnects having the first pitch in the first direction and each coupled to a first metal interconnect of the plurality of first metal interconnects.

26. The IC package of claim 25, wherein the first pitch is smaller than the second pitch.

27. The IC package of claim 25, wherein the first pitch is larger than the second pitch.

28. The IC package of claim 25, wherein each first RDL interconnect of the plurality of first RDL interconnects has a first axis intersecting the first metal interconnect in a second direction orthogonal to the first direction.

29. The IC package of claim 25, wherein:
the package substrate comprises a cored package substrate comprising a core layer adjacent to the first metallization layer in a second direction orthogonal to the first direction; and
the capacitor package is at least partially embedded in the core layer.

30. The IC package of claim 25, wherein:
the package substrate comprises a coreless package substrate; and
the package substrate is at least partially embedded in the first metallization layer.
